(19) United States
(12) Patent Application Publication
(10) Pub. No.: US 2026/0269750 A1
(43) Pub. Date: Sep. 10, 2026

(54) JAMMED DC MOTOR DETECTION METHOD

(71) Applicant: Textron Aviation Inc., Wichita, KS (US)

(72) Inventor: Clinton Lee Thompson, Wichita, KS (US)

(21) Appl. No.: 19/071,258

(22) Filed: Mar. 5, 2025

(51) Int. Cl. H02P 6/12; B64D 33/08; B64D 45/00; G01K 7/16; G01R 15/14; G01R 19/165

(52) U.S. Cl. CPC H02P 6/12; B64D 33/08; B64D 45/00; G01K 7/16; G01R 15/146; G01R 19/1659; B64D 2045/0085

(57) ABSTRACT

A system and method for determining that a DC motor is jammed, including steps of determining a current being provided to a DC motor and deriving a current variance of the current being provided to the DC motor. The method also includes determining that the current being provided to the DC motor has remained above a current threshold for a threshold amount of time and determining that the current variance has remained below a variance threshold for the threshold amount of time. Furthermore, the method may also include a step of outputting to an aircraft diagnostics system an indication that the DC motor is jammed based on the determination that the current variance has remained below the variance threshold for the threshold amount of time and that the current being provided to the DC motor has remained above the current threshold for the threshold amount of time.

### BACKGROUND OF THE INVENTION

In some aircrafts, cockpit/cabin temperature control systems utilize an RTD such as a Zone RTD to measure/monitor temperature in respective zones such as the cockpit or the cabin of an aircraft. “RTD” stands for “Resistance Temperature Detector” and is a highly accurate sensor that measures temperature by detecting changes in its electrical resistance as the temperature fluctuates. A small fan (e.g., a Zone RTD Fan) may blow air across the Zone RTD to ensure an accurate and responsive temperature measurement. The Zone RTD Fan can be driven by a brushless DC motor, for example. If the Zone RTD Fan becomes mechanically jammed due to the installation or interiors pressing up against the fan, then the Zone RTD's temperature measurement does not accurately measure the temperature in the respective zone (e.g., the cockpit or cabin) and causes poor control by the control system, resulting in uncomfortable conditions for passengers, as the system ends up making the cockpit or cabin too hot and/or too cold.

Thus, there is a need for systems or methods of detecting RTD fan jams that overcome the deficiencies of the prior art.

### SUMMARY OF THE INVENTION

Embodiments of the current invention address one or more of the above-mentioned problems and provide a distinct advance in the art of DC motors. In one embodiment, a system has a DC motor and a processing element electrically coupled to the DC motor. The processing element may be programmed to derive a current variance of a current being provided to the DC motor, determine that the current variance is below a variance threshold, and output to a diagnostics system an indication that the DC motor is jammed based on the determination that the current variance is below the variance threshold.

In another embodiment, an aircraft temperature control system includes a resistance temperature detector (RTD), a fan comprising, and a control assembly. The fan may include fan blades directed to blow air across the RTD when rotated, and a DC motor coupled to the fan blades and rotatably driving the fan blades during operation of the DC motor. The control assembly may include a microcontroller electrically coupled to the DC motor and programmed to derive a current variance of a current being provided to the DC motor, determine that the current variance has remained below a variance threshold for at least a duration of a time threshold, and output to an aircraft diagnostics system an indication that the fan is jammed based on the determination that the current variance has remained below the variance threshold for at least the duration of the time threshold.

A method of determining that a DC motor is jammed, including steps of determining a current being provided to a DC motor, deriving a current variance of the current being provided to the DC motor, determining that the current being provided to the DC motor has remained above a current threshold for a threshold amount of time, and determining that the current variance has remained below a variance threshold for the threshold amount of time. The method may also include a step of outputting to an aircraft diagnostics system an indication that the DC motor is jammed based on the determination that the current variance has remained below the variance threshold for the threshold amount of time and that the current being provided to the DC motor has remained above the current threshold for the threshold amount of time.

This summary is provided to introduce a selection of concepts in a simplified form that are further described below in the detailed description. This summary is not intended to identify key features or essential features of the claimed subject matter, nor is it intended to be used to limit the scope of the claimed subject matter. Other aspects and advantages of the current invention will be apparent from the following detailed description of the embodiments and the accompanying drawing figures.

### BRIEF DESCRIPTION OF DRAWINGS

Embodiments of the current invention are described in detail below with reference to the attached drawing figures, wherein:

FIG. 1 is a schematic drawing of a system for determining that a DC motor is jammed in accordance with embodiments described herein;

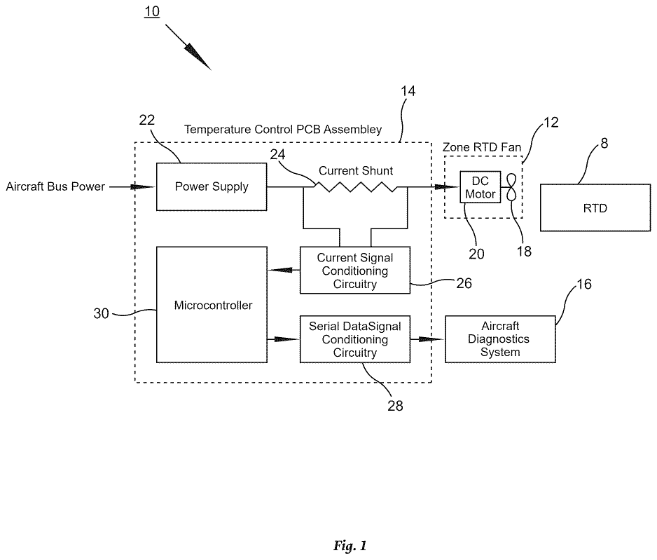

FIG. 2a is a first portion of a flow chart depicting a method of detecting mechanical jamming of the DC motor of FIG. 1, in accordance with embodiments described herein;

FIG. 2b is a second portion of the flow chart of FIG. 2a, in accordance with embodiments described herein;

FIG. 2c is a third portion of the flow chart of FIGS. 2a and 2b, in accordance with embodiments described herein;

FIG. 2d is a fourth portion of the flow chart of FIGS. 2a-2c, in accordance with embodiments described herein; and

FIG. 3 is a graph depicting exemplary current and current variance detected when the DC motor of FIG. 1 is mechanically jammed.

The drawing figures do not limit the current invention to the specific embodiments disclosed and described herein. The drawings are not necessarily to scale, emphasis instead being placed upon clearly illustrating the principles of the invention.

### DETAILED DESCRIPTION OF THE INVENTION

The following detailed description of the technology references the accompanying drawings that illustrate specific embodiments in which the technology can be practiced. The embodiments are intended to describe aspects of the technology in sufficient detail to enable those skilled in the art to practice the technology. Other embodiments can be utilized and changes can be made without departing from the scope of the current invention. The following detailed description is, therefore, not to be taken in a limiting sense. The scope of the current invention is defined only by the appended claims, along with the full scope of equivalents to which such claims are entitled.

As described herein, a cockpit and/or cabin temperature control system may utilize an RTD 8 such as a Zone RTD to measure/monitor temperature in respective zones such as the cockpit or the cabin of an aircraft. “RTD” stands for “Resistance Temperature Detector” and is a highly accurate sensor that measures temperature by detecting changes in the RTD's electrical resistance as the temperature fluctuates. A system 10 including a fan 12 (e.g., a Zone RTD Fan) and a control assembly 14 may utilize the fan 12 to blow air across the RTD 8 to ensure an accurate and responsive temperature measurement. Furthermore, the control assembly 14 may be configured to detect conditions indicating that the fan 12 is jammed, in order to notify an aircraft diagnostics system 16 or the like. Although position sensors on the fan or the motor associated therewith can be used to indicate that the fan or its motor is jammed (i.e., the position sensor indicates that the fan is not spinning), not all existing circuitry includes such sensors, and the addition of such position sensors can increase the cost of the aircraft system.

Thus, the system 10 herein may utilize existing processing elements and circuitry to detect current variance or noise in the current that is fed to the fan 12 or its motor, and determine that the fan is jammed if the current variance or noise is below a particular threshold. This is advantageous because if the fan 12 becomes mechanically jammed or otherwise jammed then the RTD's temperature measurement does not accurately measure the temperature in the respective zone (e.g., the cockpit or cabin) and causes poor control of the temperature in the cockpit or cabin. In response to detecting that the fan 12 is jammed, maintenance workers can later access this information to know where to start with repairs. Additionally or alternatively, the temperature control system and/or the flight crew can receive an indication that the fan 12 is jammed and the flight crew may manually set or adjust cockpit and/or cabin temperatures and generally ignore the RTD 8 or Zone RTD sensor until such a time as the mechanical jam can be cleared or fixed. In yet another embodiment, the temperature control system can automatically be placed into a safe state (e.g., fully cold state or the like) and/or stop using the RTD 8 to determine what temperature adjustments to make. The safe state for a temperature control system may be any setting at which resulting temperatures cannot pose a safety risk for individuals on the aircraft or components of the aircraft. For example, on an aircraft, a fully cold state may be safe, while a fully hot state can create dangerous conditions for the flight crew and/or components of the aircraft.

In some embodiments of the invention, the fan 12 may include fan blades 18 and a fan motor 20. The fan blades 18 can be driven by the fan motor 20. The fan motor 20 may be a brushless DC motor or a brushed DC motor. In alternative embodiments, the fan 12 may be replaced by a DC motor that is not associated with a fan without departing from the scope of the technology herein. For example, in some alternative embodiments, the system 10 described herein can be utilized for detecting jamming of any DC motor, whether or not that motor is being used to run a fan that cools the RTD 8 via sensing of variance or noise in the current to the DC motor. The fan blades 18 and/or the fan motor 20 can be mechanically jammed for a number of reasons, such as interior surfaces being pressed against the fan blades 18 or corrosion of components associated with the fan 12 (e.g., the fan blades 18 and/or the fan motor 20). In some embodiments, the DC motor or fan motor 20 comprises a commutator and coils configured to continuously rotate during unjammed operation based on switching of current direction by the commutator.

The control assembly 14 can be an existing control assembly for the RTD 8 or a Zone RTD, or may be any control assembly known in the art, including circuitry, processing elements, memory, and/or the like. In some embodiments, the control assembly 14 may include a power supply 22, a current shunt resistor 24, current signal conditioning circuitry 26, serial data signal conditioning circuitry 28, and/or a microcontroller 30. The control assembly 14 may be, for example, a temperature control printed circuit board (PCB) assembly or other control circuitry configured to provide a voltage required by the fan motor 20 for proper operation. For example, the voltage provided may be 5 VDC. However, in other embodiments this voltage could be any voltage up to, and including, the aircraft bus voltage without departing from the scope of the technology described herein. That is, in some embodiments, the power supply 22 can receive power from aircraft bus power or other power sources within an aircraft (e.g., 28 volts). Furthermore, the power supply 22 can additionally or alternatively include conditioning circuitry for converting power received from the aircraft bus power or other sources into voltage usable by the fan motor 20.

The control assembly 14 is configured to measure current sourced to the fan motor 20 using the current shunt resistor 24 and associated circuitry to differentially measure, filter, and gain the voltage across the current shunt resistor 24. Prior to being fed into the microcontroller 30, the current signal conditioning circuitry 26 may measure the current across the current shunt resistor 24 by measuring it differentially and/or may then place a gain on the current prior to feeding it to the microcontroller 30. Other current signal conditioning may be performed by the current signal conditioning circuitry 26 without departing from the scope of the technology described herein.

The microcontroller 30 comprises processors, processing elements, and/or memory as described herein, and is programmed to read the conditioned voltage, such as by using an Analog to Digital Converter (ADC). The ADC may be internal or external to the microcontroller 30. The software converts the voltage from the ADC to a value that represents the current sourced to the fan motor 20. This value may be referred to herein as the fan current. Whenever the fan 12 is spinning and the fan motor 20 is spinning, the motor 20 has to commutate in order to make the DC motor rotate, and that switching of coils causes noise in the current measurement. In some embodiments, whenever the motor or the fan 20 is spinning, this noise or variance is present in the fan current, but when the motor and/or the fan 20 is jammed, that noise or variance drops below a particular variance threshold level. The microcontroller 30 may be configured to detect this drop in the noise or variance as an indication of a jam and/or may require the variance or noise to drop below that variance threshold for a particular amount of time and for the fan current to be above a particular current threshold in order for the microcontroller 30 to indicate that a fan or motor jam has occurred, as later described herein. In some embodiments, the variance or noise dropping below the variance threshold for a particular amount of time may on its own indicate that the fan 12 is jammed. In other embodiments, the microcontroller 30 sensing that the fan current is above the current threshold may on its own indicate that the fan 12 or its motor is jammed. However, in some embodiments the fan current may also be higher than the current threshold due to cold temperatures. For example, in some embodiments, the fan may draw more current when it is cold or below a particular temperature threshold than when the fan 12 or its motor is jammed. Thus, in some embodiments, the microcontroller 30 may be configured and/or programmed to use a combination of both the fan current and the noise or variance drop to determine that the fan 12 or its motor is jammed.

For example, the microcontroller 30 may be configured and/or programmed to sample the ADC and derive the fan current once every 100 ms (or any pre-selected time period) and keep a running buffer of the last 128 samples (or any pre-selected number of samples) of the fan current. The microcontroller 30 may also be configured and/or programmed to then derive a variance of the samples of the fan current (e.g., the last 128 samples or a running 12.8 second window of data). This variance may be referred to herein as a fan current variance and/or current noise without departing from the scope of the technology described herein. Furthermore, although population variance is disclosed herein as an example variance, note that sample variance can be used instead without departing from the scope of the technology disclosed herein. That is, in some example embodiments, the microcontroller 30 is configured and/or programmed to use the population variance derivation to infer or quantify an amount of noise within the fan current, or alternatively can calculate the sample variance to infer or quantify the amount of noise within the fan current.

For example, variance or fan current variance may be derived per the following equation:

$$Variance = \frac{1}{128} * {\sum }_{i = 0}^{127} {( {x}_{i} - u )}^{2}$$

Where xᵢ is the input sample and u is the average of the 128 input samples, which is calculated per the following:

$$u = \frac{1}{128} * {\sum }_{i = 0}^{127} {x}_{i}$$

Note that the Variance equation can be re-arranged to the following for the ease of implementation:

$$Variance = ( \frac{1}{128} * {\sum }_{i = 0}^{127} {x}_{i}^{2} ) - {u}^{2}$$

### Substituting u:

$$Variance = ( \frac{1}{128} * {\sum }_{i = 0}^{127} {x}_{i}^{2} ) - {( \frac{1}{128} * {\sum }_{i = 0}^{127} {x}_{i} )}^{2}$$

Rearranging the constants to get the final implementation equation:

$$Variance = \frac{1}{16384} ( ( 128 * - {\sum }_{i = 0}^{127} {x}_{i}^{2} ) - {( {\sum }_{i = 0}^{127} {x}_{i} )}^{2} )$$

In some example embodiments, the microcontroller 30 may be configured and/or programmed to set a “fan jammed” fault flag if the fan current is greater than or equal to 80 mA and the fan current variance is less than 0.01 mA² for 60 seconds. The fan jammed fault flag described herein can be any electronic indication stored in memory or the like in the microcontroller 30 or communicated from the microcontroller 30 based on the fan current reaching or being greater than the current threshold and the fan current variance reaching or being less than the variance threshold for a given threshold period of time. Furthermore, the microcontroller 30 may be configured and/or programmed to clear the fan jammed fault flag if the fan current is less than 80 mA or the fan current variance is greater than 0.04 mA² for 5 seconds. However, each of these example current, variance, and time thresholds are specific to an exemplary fan motor for a Zone RTD fan motor and can be altered, reprogrammed in the microcontroller 30, adjusted, or otherwise tuned for different motors without departing from the scope of the technology described herein. Furthermore, a first variance threshold or jammed threshold may be used to set the fan jammed fault flag, while a different second variance threshold or spinning threshold may be used to clear the fan jammed fault flag in some example embodiments. Either of these variance thresholds may generally be set to a point less than the current variance (or noise present in the current) during the unjammed operation of the DC motor, but greater than the current variance typical when jams are experienced (e.g., variance converges to zero or close thereto, as described herein). The microcontroller 30 may be further configured and/or programmed to transmit the fan jammed fault flag through the serial data signal conditioning circuitry 28 and/or on to the aircraft diagnostics system 16 to be recorded, displayed, and/or otherwise processed thereby.

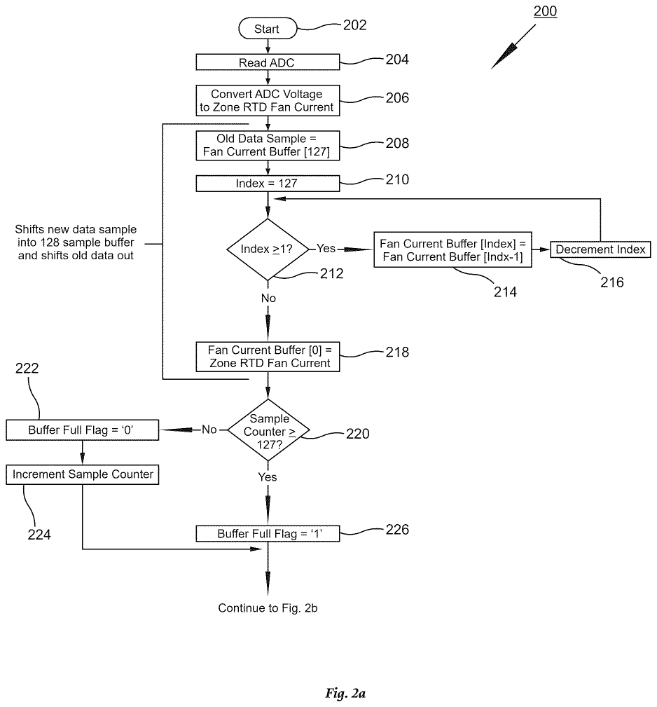

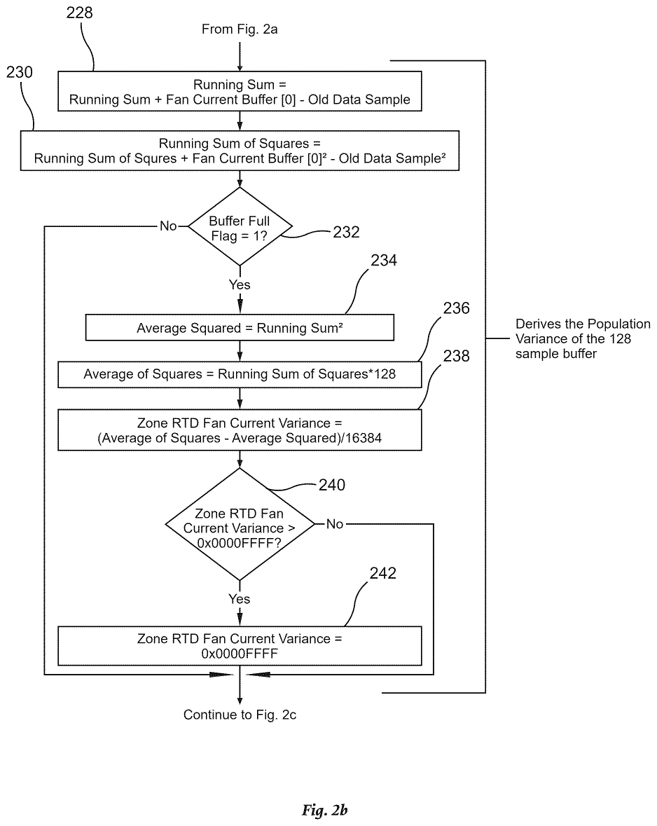

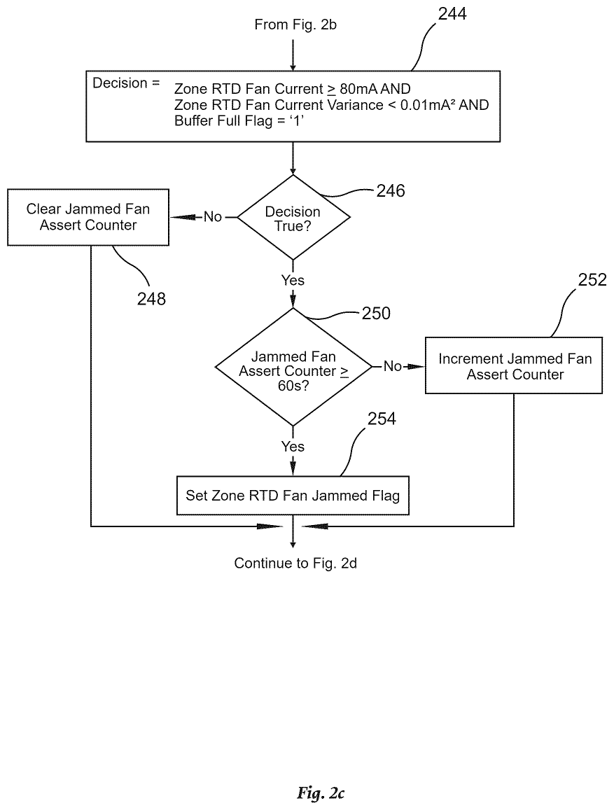

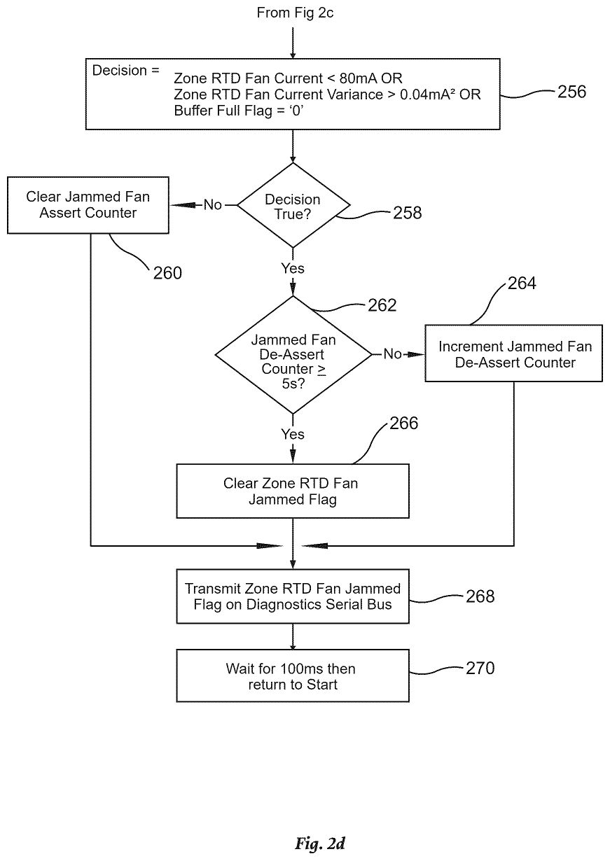

The flow chart of FIGS. 2a-2d depicts an exemplary method 200 for detecting the fan 12 being jammed in more detail. In some embodiments, various steps may be omitted, or steps may occur out of the order depicted in FIG. 2 without departing from the scope of the technology as described herein. For example, two blocks shown in succession in FIG. 2 may in fact be executed substantially concurrently, or blocks may sometimes be executed in the reverse order depending upon the functionality involved. In some example embodiments, the method 200 may be implemented by the microcontroller 30 and/or other processing elements, circuitry or the like via software, circuit configurations, or a combination thereof.

In some embodiments, the method 200 begins at the start step labeled 202 in FIG. 2a. Then the method 200 may include reading the ADC conditioned voltage, as depicted in block 204, and converting ADC voltage to Zone RTD Fan Current or the fan current described elsewhere herein, as depicted in block 206. Next, new data samples are shifted into the running buffer (e.g., a 128 sample buffer) and old data is shifted out of the running buffer, as depicted in blocks 208-218.

The method 200 also includes steps for continuing to incrementally increase a sample counter until the sample counter is greater than or equal to 127 or otherwise indicates that the running buffer is full, as depicted in blocks 220-226. Next, the method 200 includes steps for deriving the variance or fan current variance of the full sample buffer (e.g., the 128 sample buffer), as depicted in blocks 228-242 in FIG. 2b. Furthermore, as depicted in FIG. 2c, the method 200 includes a step for determining if the fan current is greater than or equal to a current threshold value (e.g., 80 mA) and the fan current variance is less than a current variance first threshold value (e.g., 0.01 mA²), as depicted in block 244. In some embodiments, the step in block 244 may also determine if the running buffer flag is full (e.g., flag=1). The method 200 may further determine, as depicted in block 246, if each of the conditions in block 244 are not met, resulting in a jammed fan assert counter being cleared as in block 248, or that each of the conditions in block 244 are met, resulting in the jammed fan assert counter being increased if a first threshold time (e.g., 60 seconds) has not yet been reached or resulting in a fan jammed flag being set, as depicted in blocks 250-254 in FIG. 2c.

The method 200, as depicted in FIG. 2d, may further include determining if the fan current is less than the current threshold (e.g., less than 80 mA) OR the fan current variance is greater than a current variance second threshold value (e.g., greater than 0.04 mA²), as depicted in block 256. Note that in some alternative embodiments, the current variance first threshold and the current variance second threshold may be the same, but are shown herein as different values. In some embodiments, the step in block 256 may also determine if the running buffer is no longer full (e.g., flag=0). The method 200 may further determine, as depicted in block 258, if each of the conditions in block 256 are not met, resulting in a jammed fan de-assert counter being cleared as in block 260, or that each of the conditions in block 256 are met, resulting in the jammed fan de-assert counter being increased if a second threshold time (e.g., 5 seconds) has not yet been reached or resulting in a fan jammed flag being cleared, as depicted in blocks 262-266 in FIG. 2d. Note that in some alternative embodiments, the first threshold time and the second threshold time may be equal without departing from the scope of the technology disclosed herein. The method 200 can further include a step of transmitting the fan jammed flag, as depicted in block 268. That is, once the fan jammed flag is set, as in FIG. 2c, and conditions have not yet been met for the fan jammed flag to be cleared per the corresponding steps in FIG. 2d, the microcontroller 30 may be configured and/or programmed to transmit the fan jammed flag or fan jammed fault flag through the serial data signal conditioning circuitry 28 and/or on to the aircraft diagnostics system 16 to be recorded, displayed, and/or otherwise processed thereby.

For example, in response to detecting via the fan jammed fault flag that the fan 12 is jammed, maintenance workers can later access this information (e.g., via the aircraft diagnostics system 16) to determine where to start with repairs. Additionally or alternatively, the temperature control system and/or the aircraft diagnostic system 16 may notify the flight crew that the DC motor or the fan 12 is jammed, and the crew may manually set or adjust cockpit and/or cabin temperatures or otherwise instruct the aircraft to ignore the RTD 8 or Zone RTD sensor until such a time as the jam can be cleared or fixed (e.g., the microcontroller 30 indicates via clearing of the fan jammed flag that the jam is cleared). In yet another embodiment, the temperature control system can automatically be placed into a safe state (e.g., fully cold state or some other safe state) in response to the fan jammed flag being set, and the system 10 can stop using the RTD 8 to determine what temperature adjustments to make due to the fan jam flag being set. In some embodiments, the DC motor or the fan motor 20 may be current limited and can continue to have current fed thereto even when jammed. However, in other alternative embodiments, particularly for DC motors that are not current limited, the fan 12 or its motor can be turned off and/or disconnected from current being fed thereto when the fan jammed flag is set indicating that the fan 12 and/or the fan motor 20 is jammed.

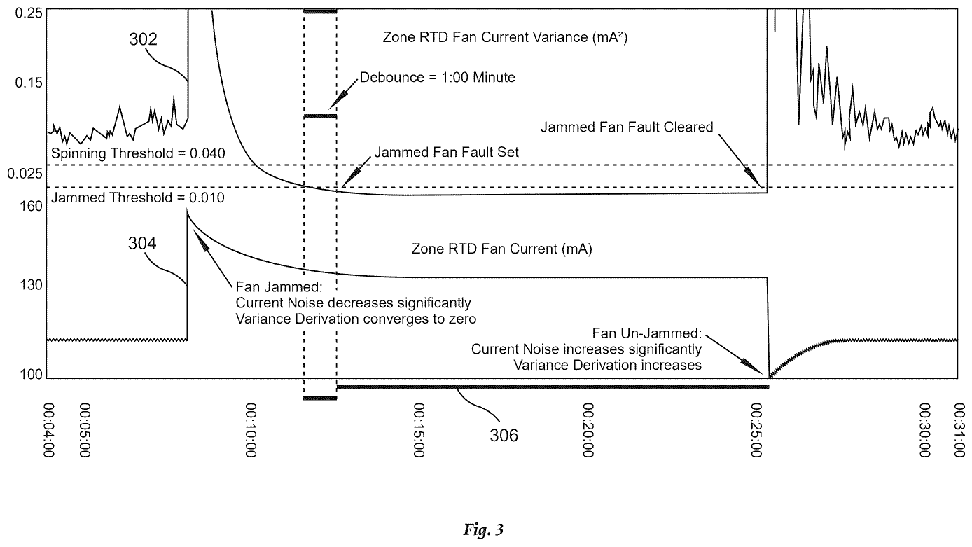

FIG. 3 provides a data plot of the fan current and the derived fan current variance under a test condition in which the fan 12 was mechanically jammed and then un-jammed. Note that when the fan 12 is jammed, the noise in the fan current 304 decreases and the fan current variance 302 converges to zero. The fan jammed fault flag is set 306 after the fan current variance is less than a preset “jammed threshold” for 60 seconds in this example embodiment charted in FIG. 3. Once the fan 12 is unjammed, the noise in the fan current 304 increases and the fan current variance 302 increases above a “spinning threshold,” which causes the fan jammed fault flag to clear.

As can be seen in FIG. 3, when the fan 12 is jammed in this example embodiment, the fan current increases to approximately 133 mA, with a normal operation value for this particular test condition being approximately 112 mA. Testing of the system 10 and methods described herein was accomplished with a Zone RTD fan cold soaked at −40° C. (e.g., an exemplary minimum aircraft operating temperature) and the Zone RTD fan's normal operation current increased to approximately 140 mA, which is greater than the jammed fan current at room temperature. This increase in normal operation current at cold soaked conditions is why current level alone cannot be used to detect if the fan 12 is jammed. The testing charted in FIG. 3 was performed at room temperature. Furthermore, the same testing conditions charted in FIG. 3 were performed at −40° C. and 55° C. to verify that the jammed fan fault detection method using both the fan current level and the fan current variance does function as intended throughout the operating envelope of a Zone RTD fan.

Throughout this specification, references to “one embodiment”, “an embodiment”, or “embodiments” mean that the feature or features being referred to are included in at least one embodiment of the technology. Separate references to “one embodiment”, “an embodiment”, or “embodiments” in this description do not necessarily refer to the same embodiment and are also not mutually exclusive unless so stated and/or except as will be readily apparent to those skilled in the art from the description. For example, a feature, structure, act, etc. described in one embodiment may also be included in other embodiments, but is not necessarily included. Thus, the current invention can include a variety of combinations and/or integrations of the embodiments described herein.

Although the present application sets forth a detailed description of numerous different embodiments, it should be understood that the legal scope of the description is defined by the words of the claims set forth at the end of this patent and equivalents. The detailed description is to be construed as exemplary only and does not describe every possible embodiment since describing every possible embodiment would be impractical. Numerous alternative embodiments may be implemented, using either current technology or technology developed after the filing date of this patent, which would still fall within the scope of the claims.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Certain embodiments are described herein as including logic or a number of routines, subroutines, applications, or instructions. These may constitute either software (e.g., code embodied on a machine-readable medium or in a transmission signal) or hardware. In hardware, the routines, etc., are tangible units capable of performing certain operations and may be configured or arranged in a certain manner. In example embodiments, one or more computer systems (e.g., a standalone, client or server computer system) or one or more hardware modules of a computer system (e.g., a processor or a group of processors) may be configured by software (e.g., an application or application portion) as computer hardware that operates to perform certain operations as described herein.

In various embodiments, computer hardware, such as a processing element, may be implemented as special purpose or as general purpose. For example, the processing element may comprise dedicated circuitry or logic that is permanently configured, such as an application-specific integrated circuit (ASIC), or indefinitely configured, such as an FPGA, to perform certain operations. The processing element may also comprise programmable logic or circuitry (e.g., as encompassed within a general-purpose processor, the microprocessor 30, or other programmable processor) that is temporarily configured by software to perform certain operations. It will be appreciated that the decision to implement the processing element as special purpose, in dedicated and permanently configured circuitry, or as general purpose (e.g., configured by software) may be driven by cost and time considerations.

Accordingly, the term “processing element” or equivalents should be understood to encompass a tangible entity, be that an entity that is physically constructed, permanently configured (e.g., hardwired), or temporarily configured (e.g., programmed) to operate in a certain manner or to perform certain operations described herein. Considering embodiments in which the processing element is temporarily configured (e.g., programmed), each of the processing elements need not be configured or instantiated at any one instance in time. For example, where the processing element comprises a general-purpose processor configured using software, the general-purpose processor may be configured as respective different processing elements at different times. Software may accordingly configure the processing element to constitute a particular hardware configuration at one instance of time and to constitute a different hardware configuration at a different instance of time.

Computer hardware components, such as communication elements, memory elements, processing elements, and the like, may provide information to, and receive information from, other computer hardware components. Accordingly, the described computer hardware components may be regarded as being communicatively coupled. Where multiple of such computer hardware components exist contemporaneously, communications may be achieved through signal transmission (e.g., over appropriate circuits and buses) that connect the computer hardware components. In embodiments in which multiple computer hardware components are configured or instantiated at different times, communications between such computer hardware components may be achieved, for example, through the storage and retrieval of information in memory structures to which the multiple computer hardware components have access. For example, one computer hardware component may perform an operation and store the output of that operation in a memory device to which it is communicatively coupled. A further computer hardware component may then, at a later time, access the memory device to retrieve and process the stored output. Computer hardware components may also initiate communications with input or output devices, and may operate on a resource (e.g., a collection of information).

The various operations of example methods described herein may be performed, at least partially, by one or more processing elements that are temporarily configured (e.g., by software) or permanently configured to perform the relevant operations. Whether temporarily or permanently configured, such processing elements may constitute processing element-implemented modules that operate to perform one or more operations or functions. The modules referred to herein may, in some example embodiments, comprise processing element-implemented modules.

Similarly, the methods or routines described herein may be at least partially processing element-implemented. For example, at least some of the operations of a method may be performed by one or more processing elements or processing element-implemented hardware modules. The performance of certain of the operations may be distributed among the one or more processing elements, not only residing within a single machine, but deployed across a number of machines. In some example embodiments, the processing elements may be located in a single location (e.g., within a home environment, an office environment or as a server farm), while in other embodiments the processing elements may be distributed across a number of locations.

Unless specifically stated otherwise, discussions herein using words such as “processing,” “computing,” “calculating,” “determining,” “presenting,” “displaying,” or the like may refer to actions or processes of a machine (e.g., a computer with a processing element and other computer hardware components) that manipulates or transforms data represented as physical (e.g., electronic, magnetic, or optical) quantities within one or more memories (e.g., volatile memory, non-volatile memory, or a combination thereof), registers, or other machine components that receive, store, transmit, or display information.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus.

The patent claims at the end of this patent application are not intended to be construed under 35 U.S.C. § 112(f) unless traditional means-plus-function language is expressly recited, such as “means for” or “step for” language being explicitly recited in the claim(s).

Although the technology has been described with reference to the embodiments illustrated in the attached drawing figures, it is noted that equivalents may be employed and substitutions made herein without departing from the scope of the technology as recited in the claims.

Having thus described various embodiments of the technology, what is claimed as new and desired to be protected by Letters Patent includes the following:

1. A system comprising:
a DC motor; and
a processing element electrically coupled to the DC motor and configured to:
derive a current variance of a current being provided to the DC motor,
determine that the current variance is below a variance threshold, and
output to a diagnostics system an indication that the DC motor is jammed based on the determination that the current variance is below the variance threshold.

2. The system of claim 1, wherein the processing element is further configured to determine that the current variance has remained below the variance threshold for a threshold time, wherein the output to the diagnostics system of the indication that the DC motor is jammed is also based on the determination that the current variance has remained below the variance threshold for the threshold time.

3. The system of claim 1, wherein the processing element is further configured to determine a value of the current being provided to the DC motor, and determine that the current being provided to the DC motor is above a current threshold, wherein the output to the diagnostics system of the indication that the DC motor is jammed is also based on the determination that the current being provided to the DC motor is above the current threshold.

4. The system of claim 3, wherein the processing element comprises a power supply, a microcontroller, and a current shunt resistor electrically coupled in series with the power supply and the DC motor, wherein the current being provided to the DC motor is measured over the current shunt resistor.

5. The system of claim 4, further comprising signal conditioning circuitry configured for conditioning a signal provided to the microcontroller from the current shunt resistor or for conditioning a signal output by the microcontroller to the diagnostics system.

6. The system of claim 1, further comprising the diagnostics system, wherein diagnostics system is configured to communicate to maintenance personnel that the DC motor is jammed.

7. The system of claim 1, further comprising a fan having fan blades driven by the DC motor.

8. The apparatus of claim 7, further comprising a resistance temperature detector (RTD), wherein the fan is positioned to blow air across the RTD.

9. They system of claim 1, wherein the processing element is configured to instruct a temperature control system to enter a safe state based on the indication that the DC motor is jammed.

10. The system of claim 1, wherein the DC motor is a brushed motor or a brushless motor.

11. The system of claim 1, wherein the DC motor further comprises coils, and the DC motor is configured to continuously rotate during unjammed operation based on switching of current to the coils, wherein the variance threshold used by the processing element is less than the current variance during the unjammed operation of the DC motor.

12. The system of claim 1, wherein the processing element is further configured to determine that the current variance is above the variance threshold or a spinning threshold, and output to the diagnostics system an indication that the DC motor is no longer jammed based on the determination that the current variance is above the variance threshold or the spinning threshold.

13. An aircraft temperature control system comprising:
a resistance temperature detector (RTD) a fan comprising:
fan blades directed to blow air across the RTD when rotated, and
a DC motor coupled to the fan blades and configured to rotatably drive the fan blades during operation of the DC motor; and
a control assembly comprising:
a microcontroller electrically coupled to the DC motor and configured to:
derive a current variance of a current being provided to the DC motor,
determine that the current variance has remained below a variance threshold for at least a duration of a time threshold, and
output to an aircraft diagnostics system an indication that the fan is jammed based on the determination that the current variance has remained below the variance threshold for at least the duration of the time threshold.

14. The aircraft temperature control system of claim 13, wherein the microcontroller is further configured to determine a value of the current being provided to the DC motor, and determine that the current being provided to the DC motor is above a current threshold, wherein the output to the aircraft diagnostics system of the indication that the fan is jammed is also based on the determination that the current being provided to the DC motor is above the current threshold.

15. The aircraft temperature control system of claim 13, wherein the control assembly further comprises a power supply and a current shunt resistor electrically coupled in series with the power supply and the DC motor of the fan, wherein the current being provided to the DC motor is measured over the current shunt resistor.

16. The aircraft temperature control system of claim 13, wherein the microcontroller is configured to automatically operate the aircraft temperature control system in a safe state based on the indication that the fan is jammed.

17. The aircraft temperature control system of claim 13, wherein the microcontroller is further configured to determine that the current variance is above a spinning threshold, and output to the aircraft diagnostics system an indication that the fan is no longer jammed based on the determination that the current variance is above the spinning threshold.

18. A method of determining that a DC motor is jammed, the method comprising:
determining a current being provided to a DC motor;
deriving a current variance of the current being provided to the DC motor;
determining that the current being provided to the DC motor has remained above a current threshold for a threshold amount of time;
determining that the current variance has remained below a variance threshold for the threshold amount of time;
outputting to an aircraft diagnostics system an indication that the DC motor is jammed based on the determination that the current variance has remained below the variance threshold for the threshold amount of time and that the current being provided to the DC motor has remained above the current threshold for the threshold amount of time.

19. The method of claim 18, wherein determining the current being provided to the DC motor comprises measuring current across a current shunt resistor in series with a power supply and the DC motor.

20. The method of claim 18, further comprising determining that the current variance is above a spinning threshold or determining that the current being provided to the DC motor is below the current threshold; and outputting to the aircraft diagnostics system an indication that the DC motor is no longer jammed based on the determination that the current variance is above the spinning threshold or the determination that the current being provided to the DC motor is below the current threshold.
